(19) United States
(12) Patent Application Publication
(10) Pub. No.: US 2011/0150500 A1
(43) Pub. Date: Jun. 23, 2011

(54) VERTICAL CAVITY SURFACE EMITTING LASER, VERTICAL CAVITY SURFACE EMITTING LASER DEVICE, OPTICAL TRANSMISSION DEVICE, AND INFORMATION PROCESSING APPARATUS

(75) Inventors: Kazuyuki Matsushita, Kanagawa (JP); Hideo Nakayama, Kanagawa (JP); Masahiro Yoshikawa, Kanagawa (JP); Kazutaka Takeda, Kanagawa (JP)

(73) Assignee: FUJI XEROX CO., LTD., Tokyo (JP)

(21) Appl. No.: 12/775,683

(22) Filed: May 7, 2010

(30) Foreign Application Priority Data
Dec. 22, 2009 (JP) 2009-290234

(51) Int. Cl. H04B 10/04; H01S 5/18; H01L 21/28; G11B 7/00

(52) U.S. Cl. 398/182; 372/46.01; 438/29; 369/100; 257/E21.158; G9B/7

(57) ABSTRACT

A vertical cavity surface emitting laser that includes: a substrate; a first semiconductor multilayer reflector; an active region; a second semiconductor multilayer reflector; a columnar structure formed on the substrate; a current narrowing layer that is formed inside of the columnar structure, and has a conductive region surrounded by an oxidization region selectively oxidized; a first electrode that is formed at a top of the columnar structure, and defines a beam window; a first insulating film that covers the beam window; and a second insulating film of which a second refractive index is larger than the first refractive index. A reflection ratio in a second region where the second insulating film is formed is lower than a reflection ratio in a first region where only the first insulating film is formed.

### CROSS-REFERENCE TO RELATED APPLICATION

This application is based on and claims priority under 35 USC 119 from Japanese Patent Application No. 2009-290234 filed on Dec. 22, 2009.

### BACKGROUND

(i) Technical Field

The present invention relates to a vertical cavity surface emitting laser, a vertical cavity surface emitting laser device, an optical transmission device, and an information processing apparatus.

(ii) Related Art

A vertical cavity surface emitting laser (VCSEL) is used as a light source in a communication device and an image forming apparatus. Single lateral mode, high power and long service life are required for such vertical cavity surface emitting laser used as a light source. A vertical cavity surface emitting laser is generally designed to oscillate in a single lateral mode by making a current narrowing region small, but an optical output becomes small when the current narrowing region is made small.

### SUMMARY

According to an aspect of the present invention, there is provided a vertical cavity surface emitting laser device including: a substrate; a first semiconductor multilayer reflector of a first conductive type formed on the substrate; an active region formed on the first semiconductor multilayer reflector; a second semiconductor multilayer reflector of a second conductive type formed on the active region; a columnar structure that is formed from the second semiconductor multilayer reflector to the first semiconductor multilayer reflector on the substrate; a current narrowing layer that is formed inside of the columnar structure, and has a conductive region surrounded by an oxidization region selectively oxidized; a first electrode that is annular, is formed at a top of the columnar structure, is electrically connected to the second semiconductor multilayer reflector, and defines a beam window; a first insulating film that is comprised of a material of which a first refractive index is able to transmit an oscillation wavelength, and covers the second semiconductor multilayer reflector exposed by the beam window of the first electrode; and a second insulating film that is comprised of a material of which a second refractive index is able to transmit an oscillation wavelength and larger than the first refractive index, and is formed on the first insulating film so that the first insulating film at a center portion inside of the beam window is exposed. A reflection ratio of the second semiconductor multilayer reflector in a second region where the second insulating film is formed is lower than a reflection ratio in a first region where only the first insulating film is formed, and a radius of an opening of the second insulating film which exposes the fist insulating film is smaller than a radius of the conductive region.

### BRIEF DESCRIPTION OF THE DRAWINGS

Exemplary embodiments of the present invention will be described in detail based on the following figures, wherein:

FIG. 1 illustrates a plane view, and a cross-section view taken from line A-A of a vertical cavity surface emitting laser in accordance with a first exemplary embodiment of the present invention;

FIG. 2 is a plane view of a top of a mesa of the vertical cavity surface emitting laser illustrated in FIG. 1;

FIG. 3 is a table indicating reflection ratios of a region 1 and a region 2 in a beam window of a present exemplary embodiment and comparison structures;

FIG. 4A is a diagram illustrating a simulation result of a reflection ratio of the region 1 of the present exemplary embodiment, and FIG. 4B is a diagram illustrating a simulation result of a reflection ratio of the region 2 of the present exemplary embodiment;

FIG. 5A is a diagram illustrating a simulation result of a reflection ratio of the region 2 of a comparison structure 1, and FIG. 5B is a diagram illustrating a simulation result of a reflection ratio of the region 2 of a comparison structure 2;

FIGS. 6A and 6B are cross-section views for explaining a fabrication process of a vertical cavity surface emitting laser in accordance with a second exemplary embodiment of the present invention;

FIGS. 7A and 7B are cross-section views for explaining the fabrication process of the vertical cavity surface emitting laser in accordance with the second exemplary embodiment of the present invention;

FIGS. 8A and 8B are schematic cross-section views illustrating a composition of a vertical cavity surface emitting laser device in which the vertical cavity surface emitting laser of exemplary embodiments and an optical component are packaged;

FIG. 9 is a diagram illustrating a composition of a light source device using the vertical cavity surface emitting laser of exemplary embodiments; and

FIG. 10 is a schematic cross-section view illustrating a composition of an optical transmission device using the vertical cavity surface emitting laser device illustrated in FIG. 8A.

### DETAILED DESCRIPTION

A description will now be given, with reference to the accompanying drawings, of exemplary embodiments of the present invention. In the following description, a selective oxidation type vertical cavity surface emitting laser will be exemplified, and a vertical cavity surface emitting laser is abbreviated as a VCSEL. The scale in drawings is exaggerated to understand the feature of the present invention, and is not same as the scale of actual devices.

### First Exemplary Embodiment

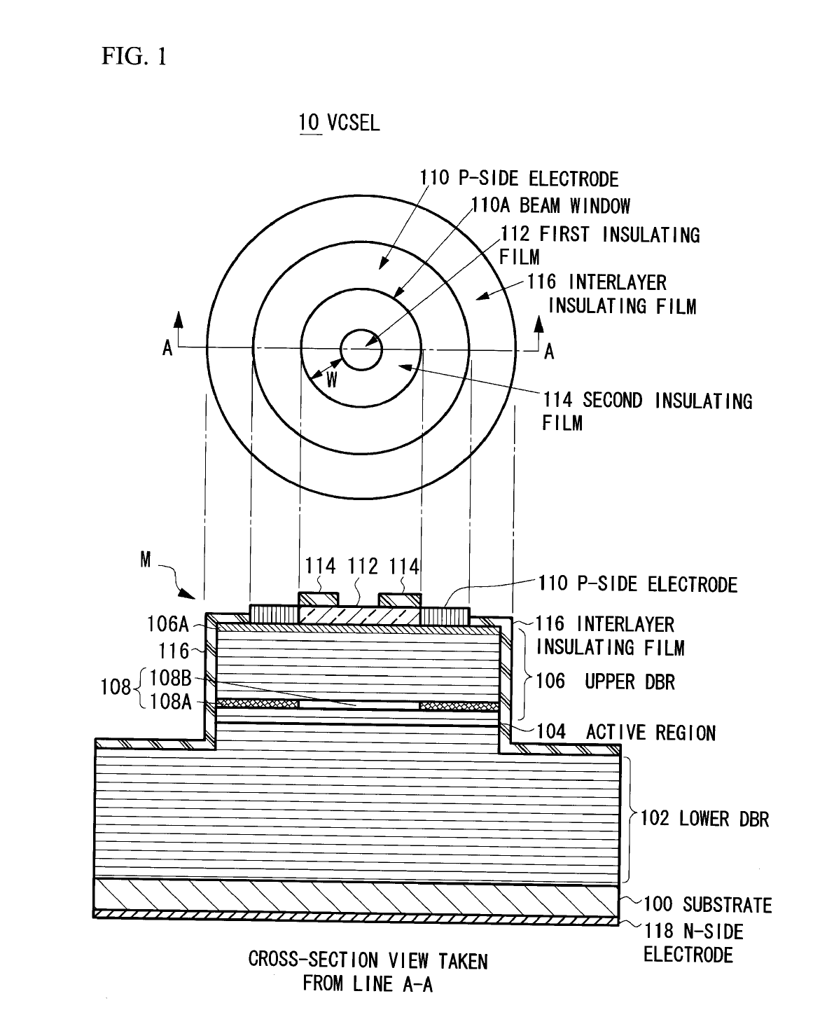

FIG. 1 is a schematic cross-section view of a VCSEL in accordance with the first exemplary embodiment of the present invention. As illustrated in FIG. 1, a VCSEL 10 of the exemplary embodiment is formed by stacking an n-type lower Distributed Bragg Reflector (hereinafter, abbreviated as DBR) 102, an active region 104, and a p-type upper DBR 106 on an n-type GaAs substrate 100. The n-type lower DBR 102 is formed by stacking AlGaAs layers with different Al composition alternately. The active region 104 includes a quantum well layer formed on the lower DBR 102, and sandwiched between upper and lower spacer layers. The p-type upper DBR 106 is formed by stacking AlGaAs layers with different Al composition on the active region 104 alternately.

The n-type lower DBR 102 is a multi-layer stack formed by a pair of an Al_{0.9}Ga_{0.1}As layer and an Al_{0.3}Ga_{0.7}As layer for example. The thickness of each layer is λ/4nᵣ (λ is an oscillation wavelength, and nᵣ is a refractive index of the medium), and the Al_{0.9}Ga_{0.1}As layer and the Al_{0.3}Ga_{0.7}As layer are stacked alternately 40 periods. A carrier concentration after doping an n-type impurity (silicon) is 3×10¹⁸ cm⁻³ for example.

The lower spacer layer of the active region 104 is an undoped Al_{0.6}Ga_{0.4}As layer, quantum well active layers are an undoped Al_{0.11}Ga_{0.89}As quantum well layer and an undoped Al_{0.3}Ga_{0.7}As barrier layer, and the upper spacer layer is an undoped Al_{0.6}Ga_{0.4}As layer.

The p-type upper DBR 106 is a multi-layer stack formed by a pair of an Al_{0.9}Ga_{0.1}As layer and an Al_{0.3}Ga_{0.7}As layer for example. The thickness of each layer is λ/4nᵣ, and the Al_{0.9}Ga_{0.1}As layer and the Al_{0.3}Ga_{0.7}As layer are stacked alternately 24 periods. A carrier concentration after doping a p-type impurity (carbon) is 3×10¹⁸ cm⁻³ for example. A contact layer 106A comprised of p-type GaAs is formed at a top layer of the upper DBR 106, and a current narrowing layer 108 comprised of p-type AlAs is formed inside of the upper DBR 106. It is preferable that the current narrowing layer 108 is close to the active region 104. The current narrowing layer 108 may be formed at the bottom layer of the upper DBR 106.

A cylindrical mesa (a columnar structure) M is formed on the substrate 100 by etching a semiconductor layer from the upper DBR 106 to a part of the lower DBR 102. The current narrowing layer 108 is exposed on the side surface of the mesa M, and has an oxidization region 108A which is selectively oxidized from the side surface, and a conductive region (oxidized aperture) 108B surrounded by the oxidization region 108A. In the oxidization process of the current narrowing layer 108, the oxidation rate of an AlAs layer is faster than that of an AlGaAs layer, and the oxidization proceeds from the side surface of the mesa M to the inside at an almost constant rate. Therefore, the planar shape of the surface, which is parallel to the principal surface of the substrate 100, of the conductive region 108B, becomes a round shape which reflects the outer shape of the mesa M, and the center of the conductive region 108B corresponds to the axial center of the mesa M which means an optical axis. The radius of the conductive region 108B may have the size at which the high-order lateral mode oscillation occurs. For example, the radius of the conductive region 108B may be equal to or larger than 5 μm in a wavelength range of 780 nm.

An annular metallic p-side electrode 110 is formed at the top of the mesa M. The p-side electrode 110 is comprised of a metal formed by stacking Au or Ti/Au for example, and is ohmic connected to the contact layer 106A of the upper DBR 106. A circular opening is formed at the center of the p-side electrode 110, and this opening defines a beam window 110A. The radius of the beam window 110A is slightly larger than the radius of the conductive region 108B, and the center of the beam window 110A substantially corresponds to the optical axis of the mesa M.

A region exposed by the beam window 110A of the p-side electrode 110 is covered by a circular first insulating film 112. The first insulating film 112 is comprised of a material that is able to transmit light with a wavelength of the oscillation wavelength. The refractive index of the first insulating film 112 is smaller than the refractive index of the semiconductor layer of the upper DBR 106. The film thickness of the first insulating film 112 is odd multiples of half of the oscillation wavelength, which means (2a−1) λ/2n₁ (a is integer, λ is an oscillation wavelength, and n₁ is a refractive index). The first insulating film 112 is comprised of a material such as SiON, SiO₂, SiN, and TiO₂. In the illustrated exemplary embodiment, the outside diameter of the first insulating film is same as that of the beam window 110A. However, the outside diameter of the first insulating film 112 may be larger than that of the beam window 110A so that the end portion of the first insulating film 112 extends on the p-side electrode.

An annular second insulating film 114 with a width of W is formed on the first insulating film 112. The second insulating film 114 is comprised of a material that is able to transmit light with a wavelength of the oscillation wavelength. The refractive index of the second insulating film 114 is larger than that of the first insulating film 112. The film thickness of the second insulating film 114 is odd multiples of a quarter of the oscillation wavelength, which means (2b−1) λ/4n₂ (b is integer, n₂ is a refractive index, and n₂>n₁). The second insulating film 114 is comprised of a material such as SiON, SiO₂, SiN, and TiO₂. The center of the second insulating film 114 substantially corresponds to the center of the conductive region 108B, and the radius of the opening of the second insulating film 114 (the radius exposing the first insulating film) is smaller than the radius of the conductive region 108B. Preferably, the width W of the second insulating film 114 corresponds to that of the region where the high-order lateral mode is generated. In the illustrated exemplary embodiment, the outside diameter of the second insulating film 114 corresponds to that of the first insulating film 112, but is not limited to the exemplary embodiment. The end portion of the second insulating film 114 may extend on the p-side electrode 110.

At the top of the mesa M, a part outside from the p-side electrode 110 is covered by the interlayer insulating film 116. The interlayer insulating film 116 extends to cover the side surface and bottom surface of the mesa M. As described later, preferably, the interlayer insulating film 116 is comprised of a same material as that of the second insulating film 114, and the second insulating film 114 and the interlayer insulating film 116 can be pattern-formed simultaneously. An n-side electrode 118 that is electrically connected to the lower DBR 102 is formed on the back side of the substrate 100.

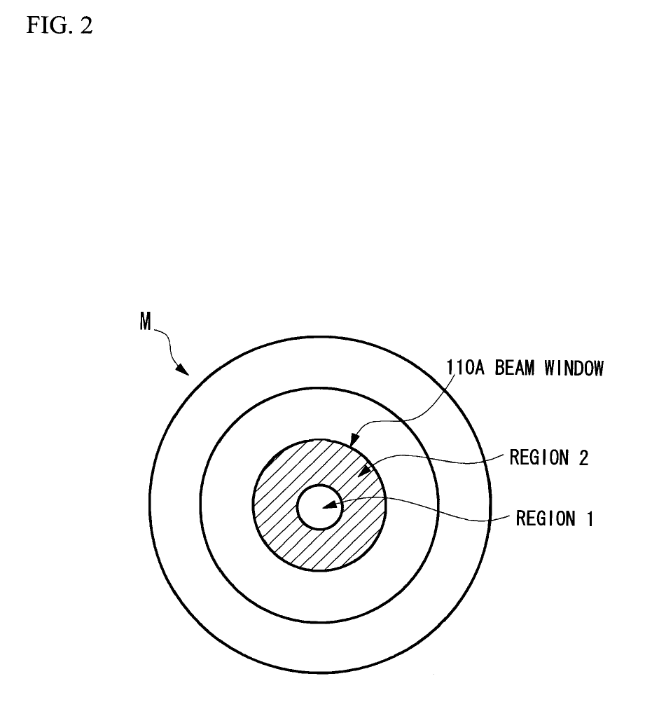

FIG. 2 illustrates a plane view of the top of the mesa of the VCSEL in FIG. 1. In the VCSEL 10 of the present exemplary embodiment, a structure inside of the beam window 110A is different between a center portion and an edge portion as illustrated in FIG. 1. A central circular region 1 illustrated in FIG. 2 is a region where only the first insulating film 112 is formed, which means a region where the first insulating film 112 is exposed by the second insulating film 114. An annular region 2 (illustrated with hatch) is a region where the second insulating film 114 is stacked on the first insulating film 112.

The region 2 makes the reflection ratio of the upper DBR 106 in the region 2 lower than the reflection ratio of the upper DBR 106 in the region 1 by including the second insulating film 114 of which the refractive index is higher than the refractive index of the first insulating film 112 and making the film thickness of the first insulating film 112 λ/2 and the film thickness of the second insulating film 114 λ/4. This accelerates a fundamental lateral mode oscillation generated near the optical axis in the region 1, and suppresses a high-order lateral mode oscillation generated away from the optical axis in the region 2. As a result, even though the radius of the conductive region 108 is made large, it is possible to obtain the high-power fundamental lateral mode oscillation because the high-order lateral mode oscillation is suppressed.

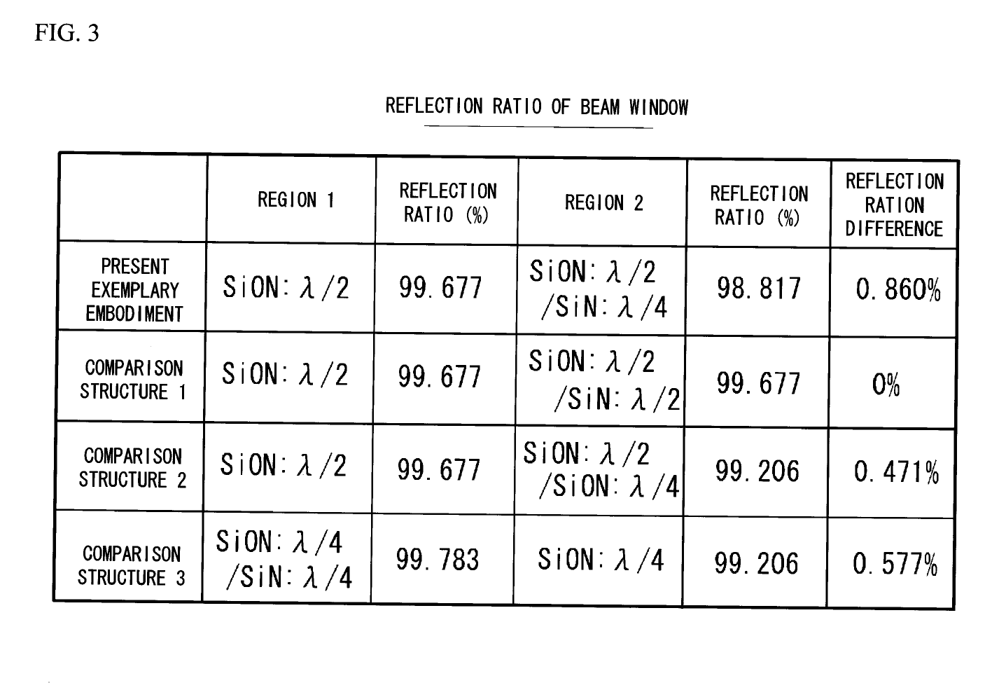

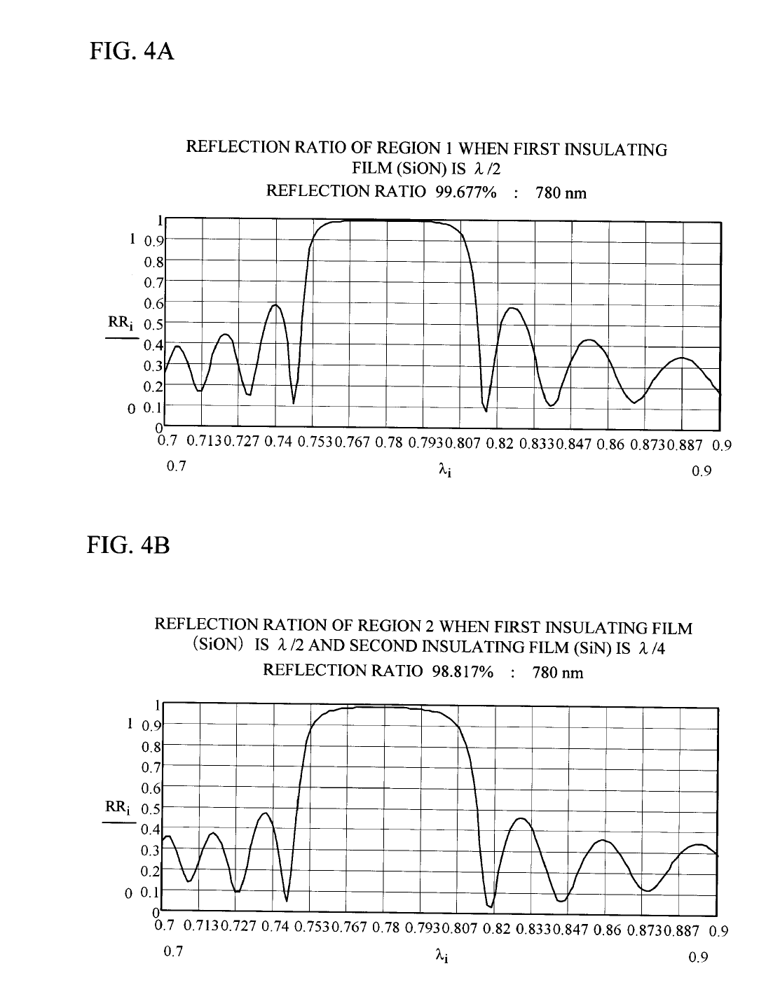

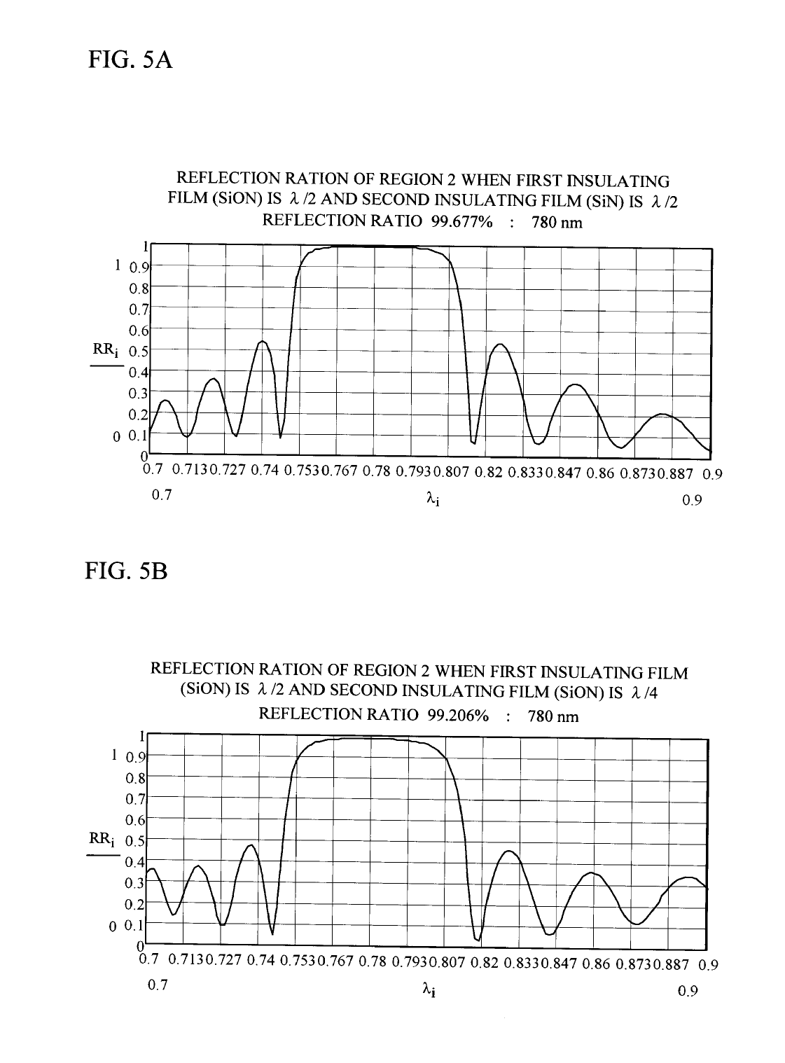

FIG. 3 is a table exemplifying reflection ratios of the region 1 and the region 2 of the beam window in the present exemplary embodiment and comparison structures. FIGS. 4A through 5B are simulation results of reflection ratios when the upper DBR is composed by stacking an Al_{0.9}Ga_{0.1}As layer and an Al_{0.3}Ga_{0.7}As layer 24 periods. In the preferable example of the present exemplary embodiment, the first insulating film 112 is comprised of SiON (refractive index=1.57) with a film thickness of λ/2, and the second insulating film 114 is comprised of SiN (refractive index=1.92) with a film thickness of λ/4. In this case, the reflection ratio of the region 1 of the upper DBR is 99.677%, and the reflection ratio of the region 2 is 98.817%. The reflection ratio difference between regions 1 and 2 is 0.860%. FIG. 4A illustrates a profile of the reflection ratio of the upper DBR in the region 1. FIG. 4B illustrates a profile of the reflection ratio of the upper DBR in the region 2.

In a comparison structure 1, the first insulating film 112 is comprised of SiON with a film thickness of λ/2, and the second insulating film 114 is comprised of SiN with a film thickness of λ/2. In this case, the reflection ratio of the upper DBR in the region 2 is 99.677%, and the reflection ratio difference is 0%. FIG. 5A illustrates a profile of the reflection ratio of the region 2.

In a comparison structure 2, the first insulating film 112 is comprised of SiON with a film thickness of λ/2, and the second insulating film 114 is comprised of SiON with a film thickness of λ/4. In this case, the reflection ratio of the upper DBR in the region 2 is 99.206%, and the reflection ratio difference is 0.471%. A profile of the reflection ratio of the region 2 is illustrated as FIG. 5B.

In a comparison structure 3, the first insulating film 112 is composed by stacking SiON with a film thickness of λ/4 and SiN with a film thickness of λ/4, and the second insulating film 114 is comprised of SiON with a film thickness of λ/4. In this case, the reflection ratio of the region 1 is 99.783%, the reflection ratio of the region 2 is 99.206%, and the reflection ratio difference is 0.577%.

As described above, it is possible to reduce the reflection ratio of the region 2 compared to the reflection ratio of the region 1 by forming the second insulating film 114 of which the film thickness is odd multiples of λ/4, and the refractive index is larger than that of the first insulating film 112, on the first insulating film 112 with a film thickness of odd multiples of λ/2. It is known that the laser oscillation becomes difficult when the reflection ratio of the upper DBR 106 becomes less than about 99%.

It is preferable to select the combination where the difference between refractive indexes of the first insulating film 112 and the second insulating film 114 becomes large. This makes the reflection ratio difference between regions 1 and 2 large. That is to say that this makes the reflection ratio of the region 2 smaller than that of the region 1 effectively.

### Second Exemplary Embodiment

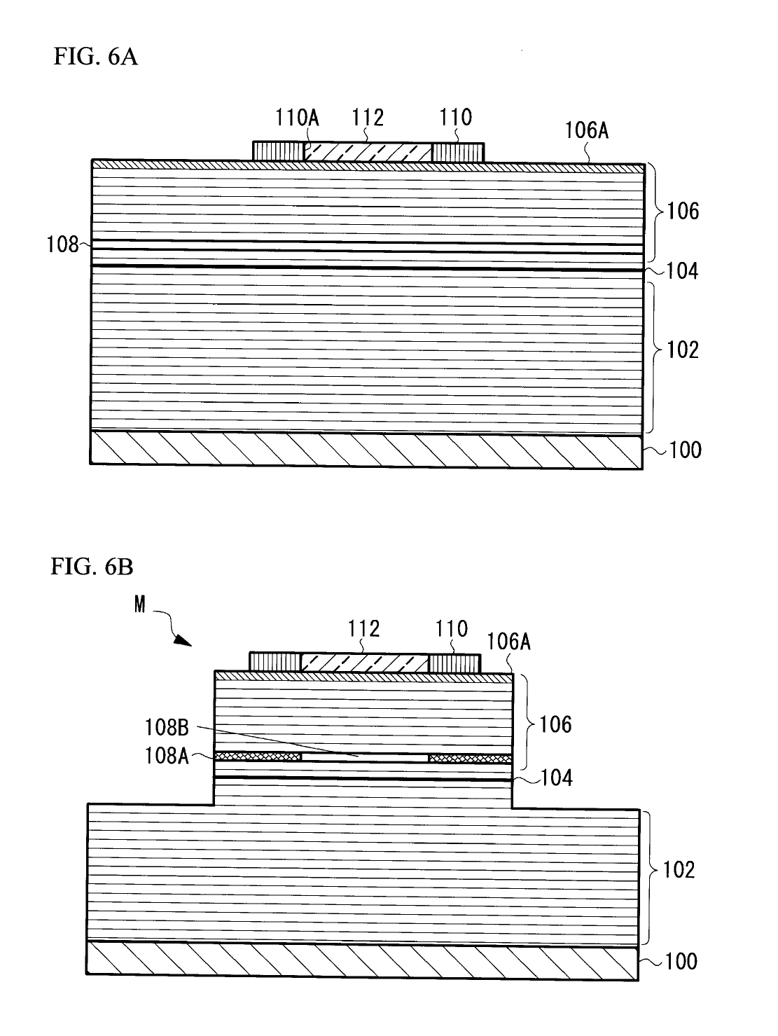

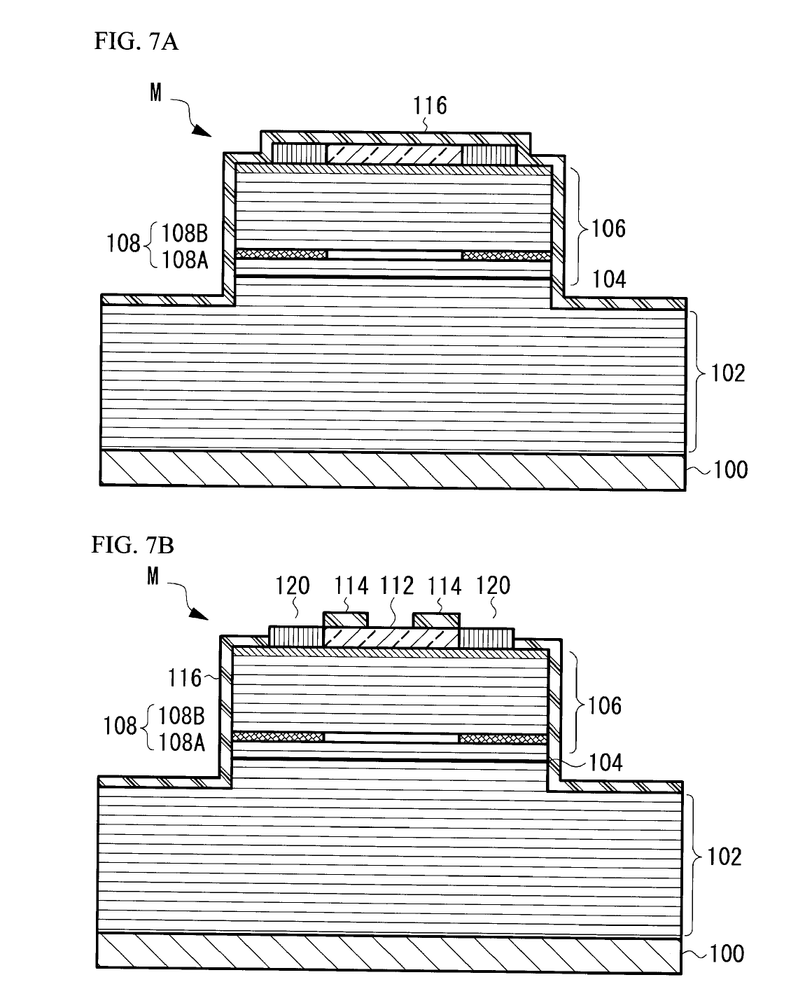

A description will now be given of the second exemplary embodiment of the present invention. The second exemplary embodiment relates to a preferable fabrication method of the VCSEL. A fabrication method is described with reference to FIGS. 6A through 7B. As illustrated in FIG. 6A, the n-type lower DBR 102, the active region 104, and the p-type upper DBR 106 are stacked on the n-type GaAs substrate 100 by the metal organic chemical vapor deposition (MOCVD) method. The n-type lower DBR 102 is composed by stacking Al_{0.9}Ga_{0.1}As and Al_{0.3}Ga_{0.7}As with a carrier concentration of 2×10¹⁸ cm⁻³ alternately 40 periods so that each film thickness becomes quarter of the wavelength of the medium. The active region 104 is comprised of an undoped Al_{0.6}Ga_{0.4}As lower spacer layer, an undoped Al_{0.11} Ga_{0.89}As quantum well layer, an undoped Al_{0.3}Ga_{0.7}As barrier layer, and an undoped Al_{0.6}Ga_{0.4}As upper spacer layer. The p-type upper DBR 106 is composed by stacking a p-type Al_{0.9}Ga_{0.1}As layer and a p-type Al_{0.3}Ga_{0.7}As layer with a carrier concentration of 3×10¹⁸ cm⁻³ alternately 24 periods so that each film thickness becomes quarter of the wavelength of the medium. The p-type GaAs contact layer 106A with a carrier concentration of 1×10¹⁹ cm⁻³ is formed at the top layer of the upper DBR 106, and a p-type AlAs layer 108 is formed at the bottom layer of the upper DBR 106 or inside of the upper DBR 106. It is not illustrated, but a buffer layer may be provided between the substrate 100 and the lower DBR 102.

A resist pattern is formed on the contact layer 106A by the photolithography process conventionally known, and the annular p-side electrode 110 comprised of Au/Ti is formed on the contact layer 106A by the liftoff process. Then, SiON is deposited on whole surface of the substrate 100 by CVD, and the circular first insulating film 112 covering the beam window 110A which is the opening of the p-side electrode 110 is formed by patterning SiON. The first insulating film 112 protects the beam window 110A from an exposure and particles generated in subsequent processes by covering the beam window 110A.

As illustrated FIG. 6B, a circular mask is formed on a region including the p-side electrode 110 and the first insulating film 112 by the photolithography process. Then, the cylindrical mesa M is formed by etching the semiconductor layer from the upper DBR 106 to the part of the lower DBR 102 by the reactive ion etching process using boron trichloride as an etching gas for example. Accordingly, the AlAs layer 108 is exposed on the side surface of the mesa M. Then the oxidization process that exposes the substrate to the water-vapor atmosphere with a temperature of 340° C. for a given time is carried out, and the oxidization region 108A which is oxidized a certain distance from the side surface of the mesa M is formed inside of the AlAs layer 108. The oxidation control is performed so that a radius of plane field of the conductive region 108B surrounded by the oxidization region 108A becomes larger than the radius needed for a conventional single lateral mode (e.g. 3 μm), and becomes the size at which the high-order lateral mode occurs (e.g. 5 μm).

Then, the mask is removed, and the interlayer insulating film 116 comprised of SiN is formed on whole surface of the substrate as illustrated in FIG. 7A. The interlayer insulating film 116 is adjusted so that the film thickness of the top of the mesa M becomes a quarter of the wavelength of the medium. Then, as illustrated in FIG. 7B, a mask is formed by the photolithography process, and the interlayer insulating film 116 exposed by the mask is removed by etching. Preferably, the interlayer insulating film 116 is etched under the etching condition that the selectivity between the interlayer insulating film 116 and the first insulating film 112 can be selected. For example, the reactive ion etching process using an etchant of SF₆+O₂ is carried out. According to this, a contact hole 120 to the p-side electrode 110 is formed at the top of the mesa M, and the annular second insulating film 114 is formed on the first insulating film 112. Then, a metallic wiring that is coupled to the p-side electrode 110 through the contact hole 120 is formed, and the n-side electrode 118 is formed on the back side of the substrate.

According to the fabrication method of the present exemplary embodiment, it is possible to form the second insulating film 114 with an easy process only changing a mask pattern by forming the second insulating film 114 and the interlayer insulating film 116 simultaneously, and mass production at low cost becomes possible. In addition, as the process is processed under the condition that the beam window 110A is protected by the first insulating film 112, this makes it work for the reliability of the VCSEL. When an insulating layer is formed inside of a contact layer by etching the contact layer, it is difficult to stop the etching with high accuracy. If the film thickness of the etched layer is not uniform, there is a possibility that a reflection ratio changes, and this makes it difficult to obtain a reproducible composition. However, the above problem does not occur in the present exemplary embodiment.

In above exemplary embodiments, a description was given of a current narrowing layer comprised of AlAs, but a current narrowing layer may be an AlGaAs layer of which the Al composition is higher than the Al composition of other DBRs. In addition, the radius of the conductive region (the oxidized aperture) of the current narrowing layer can be changed appropriately according to required optical output. Furthermore, in above exemplary embodiments, the description was given of a GaAs-based VCSEL, but the present invention can be applied to other VCSELs using other III-V group compound semiconductors. In above exemplary embodiments, the description was given of a single spot VCSEL, but the VCSEL can be a multi-spot VCSEL where multiple mesas (emission portion) are formed on the substrate, or a VCSEL array.

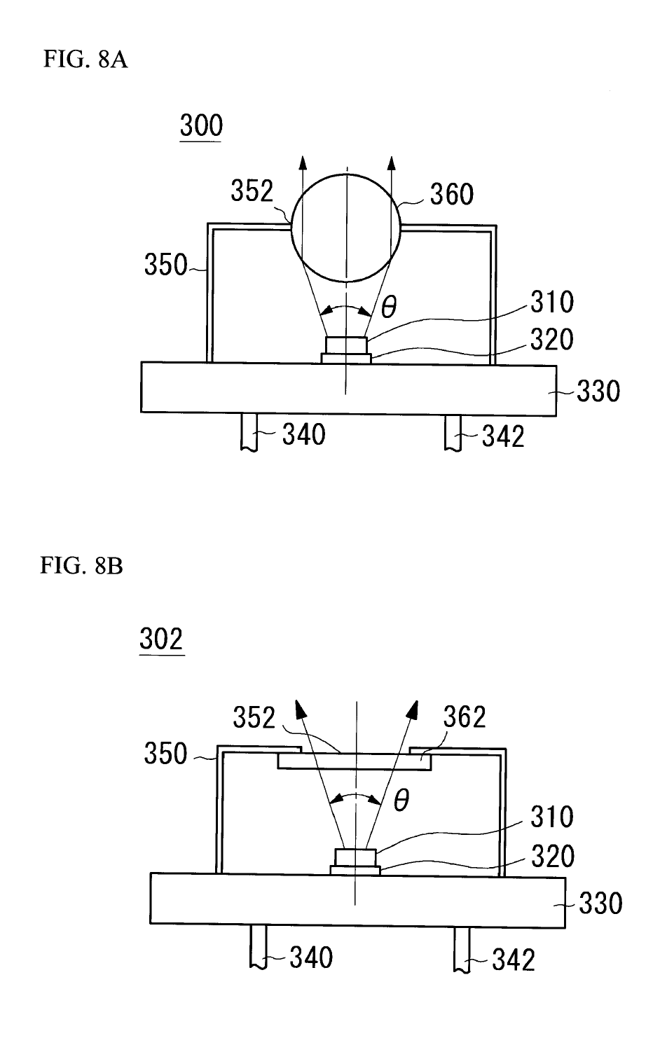

A description will be given of a vertical cavity surface emitting laser device, an optical information processing apparatus, and an optical transmission device using the VCSEL of exemplary embodiments with reference to drawings. FIG. 8A is a cross-section view illustrating a composition of a vertical cavity surface emitting laser device in which the VCSEL and an optical component are packaged. A vertical cavity surface emitting laser device 300 fixes a chip 310, on which a long resonator VCSEL is formed, to a disk-shaped metal stem 330 via a conductive bond 320. Conductive leads 340 and 342 are inserted in a through hole (not illustrated) provided to the stem 330, the lead 340 is electrically connected to the n-side electrode of the VCSEL, and the lead 342 is electrically connected to the p-side electrode.

A rectangular hollow cap 350 is fixed on the stem 330 including the chip 310, and a ball lens 360 is fixed in an opening 352 located in the center of the cap 350. The ball lens 360 is laid out so that the optical axis of the ball lens 360 corresponds to the substantial center of the chip 310. When a forward current is applied between leads 340 and 342, a laser beam is emitted from the chip 310 to the vertical direction. The distance between the chip 310 and the ball lens 360 is adjusted so that the ball lens 360 is included within the spread angle θ of the laser beam from the chip 310. A light receiving element and a temperature sensor to monitor the emitting condition of the VCSEL can be included in the cap.

FIG. 8B is a diagram illustrating a composition of another vertical cavity surface emitting laser device. A vertical cavity surface emitting laser device 302 illustrated in FIG. 8B fixes a plane glass 362 in the opening 352 located in the center of the cap 350 instead of using the ball lens 360. The plane glass 362 is laid out so that the center of the plane glass 362 corresponds to the substantial center of the chip 310. The distance between the chip 310 and the plane glass 362 is adjusted so that the opening radius of the plane glass 362 becomes equal to or larger than the spread angle θ of the laser beam from the chip 310.

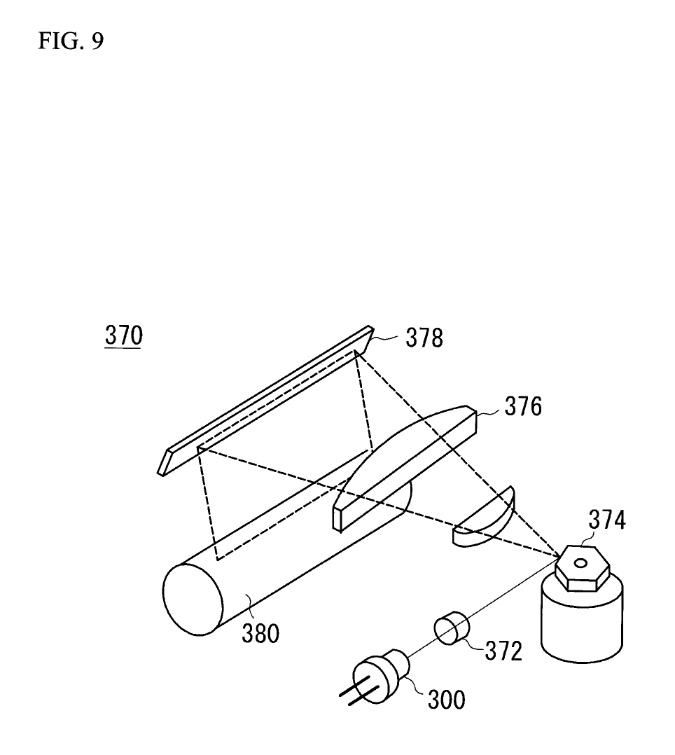

FIG. 9 is a diagram illustrating a case where the VCSEL is applied to a light source of an optical information processing apparatus. An optical information processing apparatus 370 is provided with a collimator lens 372 which receives the laser beam from the vertical cavity surface emitting laser device 300 or 302, in which the long resonator VCSEL is packaged, illustrated in FIG. 8A or 8B, a polygon mirror 374 which rotates at constant speed and reflects a beam of light from the collimator lens 372 at constant spread angle, a fθ lens 376 which receives the laser beam from the polygon mirror 374 and irradiates the laser beam to a reflection mirror 378, the linear reflection mirror 378, and a photoreceptor drum (a record medium) 380 which forms latent images based on the reflection beam from the reflection mirror 378. As described above, the laser beam from the VCSEL can be used as a light source of the optical information processing apparatus such as a copier and a printer provided with an optical system which focuses the laser beam from the VCSEL onto the photoreceptor drum and a structure which scans the focused laser beam on the photoreceptor drum.

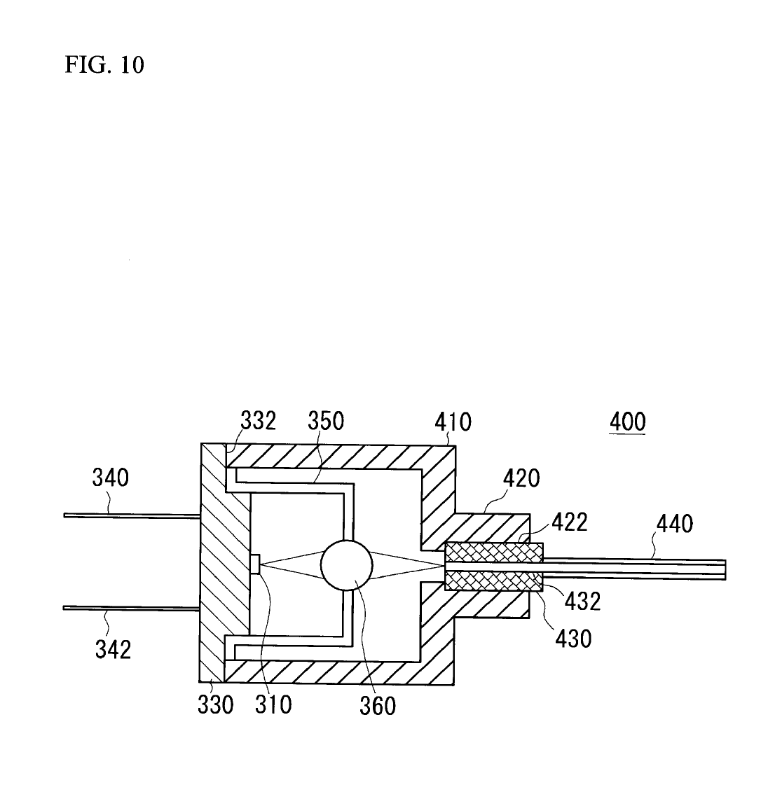

FIG. 10 is a cross-section view illustrating a composition where the vertical cavity surface emitting laser device illustrated in FIG. 8A is applied to an optical transmission device. An optical transmission device 400 includes a cylindrical chassis 410 fixed to the stem 330, a sleeve 420 integrally-formed on the end surface of the chassis 410, a ferrule 430 held in an opening 422 of the sleeve 420, and an optical fiber 440 held by the ferrule 430. The end portion of the chassis 410 is fixed to a flange 332 which is circumferentially-formed of the stem 330. The ferrule 430 is laid out in the opening 422 of the sleeve 420 accurately, and the optical axis of the optical fiber 440 is matched to the optical axis of the ball lens 360. The core of the optical fiber 440 is held in a through hole 432 of the ferrule 430.

The laser beam emitted from the surface of the chip 310 is focused by the ball lens 360. The focused beam enters to the core of the optical fiber 440, and is transmitted. In above exemplary embodiments, the ball lens 360 is used, but other lenses such as a biconvex lens and a plane-convex lens can be used besides a ball lens. Furthermore, the optical transmission device 400 can include a drive circuit to apply an electrical signal to leads 340 and 342. The optical transmission device 400 can also include a receiving function to receive an optical signal through the optical fiber 440.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various exemplary embodiments and with the various modifications as are suited to the particular use contemplated. It is intended that the scope of the invention be defined by the following claims and their equivalents.

What is claimed is:

1. A vertical cavity surface emitting laser comprising:
a substrate;
a first semiconductor multilayer reflector of a first conductive type formed on the substrate;
an active region formed on the first semiconductor multilayer reflector;
a second semiconductor multilayer reflector of a second conductive type formed on the active region;
a columnar structure that is formed from the second semiconductor multilayer reflector to the first semiconductor multilayer reflector on the substrate;
a current narrowing layer that is formed inside of the columnar structure, and has a conductive region surrounded by an oxidization region selectively oxidized;
a first electrode that is annular, is formed at a top of the columnar structure, is electrically connected to the second semiconductor multilayer reflector, and defines a beam window;
a first insulating film that is comprised of a material of which a first refractive index is able to transmit an oscillation wavelength, and covers the second semiconductor multilayer reflector exposed by the beam window of the first electrode; and
a second insulating film that is comprised of a material of which a second refractive index is able to transmit an oscillation wavelength and larger than the first refractive index, and is formed on the first insulating film so that the first insulating film at a center portion inside of the beam window is exposed,
wherein a reflection ratio of the second semiconductor multilayer reflector in a second region where the second insulating film is formed is lower than a reflection ratio in a first region where only the first insulating film is formed, and a radius of an opening of the second insulating film which exposes the fist insulating film is smaller than a radius of the conductive region.

2. The vertical cavity surface emitting laser according to claim 1, further comprising a third insulating film that covers at least a side of the columnar structure, and is comprised of a same material as that of the second insulating film.

3. The vertical cavity surface emitting laser according to claim 1, wherein a film thickness of the first insulating film is (2a−1) λ/2n₁ (a is integer, λ is an oscillation wavelength, and n₁ is a refractive index), and a film thickness of the second insulating film is (2b−1) λ4n₂ (a is integer, and n₂ is a refractive index).

4. The vertical cavity surface emitting laser according to claim 1, wherein the first insulating film is comprised of silicon oxynitride (SiON), and the second insulating film is comprised of silicon nitride (SiN).

5. A fabrication method of a vertical cavity surface emitting laser having a columnar structure on a substrate, the fabrication method comprising:
stacking a semiconductor layer including a first semiconductor multilayer reflector of a first conductive type, an active region, a current narrowing layer which is conductive, a second semiconductor multilayer reflector of a second conductive type on the substrate;
forming a first electrode which is annular and defines a beam window on the second semiconductor multilayer reflector;
forming a first insulating film that is comprised of a material having a first refractive index to an oscillation wavelength, and covers the beam window of the first electrode;
forming the columnar structure including the first electrode and the first insulating film at a top on the substrate by etching the semiconductor layer from the second semiconductor multilayer reflector to the first semiconductor multilayer reflector;
forming an oxidization region and a conductive region surrounded by the oxidization region inside of a current narrowing layer by oxidizing the current narrowing layer inside of the columnar structure selectively;
forming a second insulating film that is comprised of a material of which a second refractive index is larger than the first refractive index on whole area of the substrate including the columnar structure; and
forming a second insulating film which is annular and of which a radius is smaller than a radius of the conductive region, on the first insulating film by removing the second insulating film at the top of the columnar structure selectively,
wherein a reflection ratio of the second semiconductor multilayer reflector in a second region where the second insulating film is formed is lower than a reflection ratio in a first region where only the first insulating film is formed.

6. The fabrication method according to claim 5 wherein a film thickness of the first insulating film is (2a−1) λ/2n₁ (a is integer, λ is an oscillation wavelength, and n₁ is a refractive index), and a film thickness of the second insulating film is (2b−1) λ/4n₂ (a is integer, and n₂ is a refractive index).

7. A vertical cavity surface emitting laser device comprising:
a vertical cavity surface emitting laser including:
a substrate;
a first semiconductor multilayer reflector of a first conductive type formed on the substrate;
an active region formed on the first semiconductor multilayer reflector;
a second semiconductor multilayer reflector of a second conductive type formed on the active region;
a columnar structure that is formed from the second semiconductor multilayer reflector to the first semiconductor multilayer reflector on the substrate;
a current narrowing layer that is formed inside of the columnar structure, and has a conductive region surrounded by an oxidization region selectively oxidized;
a first electrode that is annular, is formed at a top of the columnar structure, is electrically connected to the second semiconductor multilayer reflector, and defines a beam window;
a first insulating film that is comprised of a material of which a first refractive index is able to transmit an oscillation wavelength, and covers the second semiconductor multilayer reflector exposed by the beam window of the first electrode; and
a second insulating film that is comprised of a material of which a second refractive index is able to transmit an oscillation wavelength and larger than the first refractive index, and is formed on the first insulating film so that the first insulating film at a center portion inside of the beam window is exposed,
wherein a reflection ratio of the second semiconductor multilayer reflector in a second region where the second insulating film is formed is lower than a reflection ratio in a first region where only the first insulating film is formed, and a radius of an opening of the second insulating film which exposes the fist insulating film is smaller than a radius of the conductive region; and
an optical member that receives a beam from the vertical cavity surface emitting laser.

8. An optical transmission device comprising:
a vertical cavity surface emitting laser device that comprises:
a vertical cavity surface emitting laser that includes:
a substrate;
a first semiconductor multilayer reflector of a first conductive type formed on the substrate;
an active region formed on the first semiconductor multilayer reflector;
a second semiconductor multilayer reflector of a second conductive type formed on the active region;
a columnar structure that is formed from the second semiconductor multilayer reflector to the first semiconductor multilayer reflector on the substrate;
a current narrowing layer that is formed inside of the columnar structure, and has a conductive region surrounded by an oxidization region selectively oxidized;
a first electrode that is annular, is formed at a top of the columnar structure, is electrically connected to the second semiconductor multilayer reflector, and defines a beam window;
a first insulating film that is comprised of a material of which a first refractive index is able to transmit an oscillation wavelength, and covers the second semiconductor multilayer reflector exposed by the beam window of the first electrode; and
a second insulating film that is comprised of a material of which a second refractive index is able to transmit an oscillation wavelength and larger than the first refractive index, and is formed on the first insulating film so that the first insulating film at a center portion inside of the beam window is exposed,
wherein a reflection ratio of the second semiconductor multilayer reflector in a second region where the second insulating film is formed is lower than a reflection ratio in a first region where only the first insulating film is formed, and a radius of an opening of the second insulating film which exposes the fist insulating film is smaller than a radius of the conductive region; and
an optical member that receives a beam from the vertical cavity surface emitting laser; and
a transmission unit that transmits a laser beam emitted from the vertical cavity surface emitting laser device through an optical medium.

9. An information processing apparatus comprising:
a vertical cavity surface emitting laser that includes:
a substrate;
a first semiconductor multilayer reflector of a first conductive type formed on the substrate;
an active region formed on the first semiconductor multilayer reflector;
a second semiconductor multilayer reflector of a second conductive type formed on the active region;
a columnar structure that is formed from the second semiconductor multilayer reflector to the first semiconductor multilayer reflector on the substrate;
a current narrowing layer that is formed inside of the columnar structure, and has a conductive region surrounded by an oxidization region selectively oxidized;
a first electrode that is annular, is formed at a top of the columnar structure, is electrically connected to the second semiconductor multilayer reflector, and defines a beam window;
a first insulating film that is comprised of a material of which a first refractive index is able to transmit an oscillation wavelength, and covers the second semiconductor multilayer reflector exposed by the beam window of the first electrode; and
a second insulating film that is comprised of a material of which a second refractive index is able to transmit an oscillation wavelength and larger than the first refractive index, and is formed on the first insulating film so that the first insulating film at a center portion inside of the beam window is exposed,
wherein a reflection ratio of the second semiconductor multilayer reflector in a second region where the second insulating film is formed is lower than a reflection ratio in a first region where only the first insulating film is formed, and a radius of an opening of the second insulating film which exposes the fist insulating film is smaller than a radius of the conductive region;
a focusing unit that focuses a laser beam emitted from the vertical cavity surface emitting laser onto a record medium; and
a structure which scans the laser beam focused by the focusing unit on the record medium.
